(19) United States
(12) Patent Application Publication
(10) Pub. No.: US 2026/0239777 A1
(43) Pub. Date: Aug. 13, 2026

(54) SEMICONDUCTOR LIGHT-EMITTING DEVICE

(71) Applicant: STANLEY ELECTRIC CO., LTD., Tokyo (JP)

(72) Inventors: Kenji TABUCHI, Tokyo-to (JP); Yusuke YAMASHITA, Tokyo-to (JP); Yuichi ITO, Tokyo-to (JP); Hiroki SAWADA, Tokyo-to (JP)

(73) Assignee: STANLEY ELECTRIC CO., LTD., Tokyo (JP)

(21) Appl. No.: 19/533,338

(22) Filed: Feb. 9, 2026

(30) Foreign Application Priority Data
Feb. 12, 2025 (JP) 2025-020599

(51) Int. Cl. H10H 20/82; H10H 20/825; H10H 20/831

(52) U.S. Cl. CPC H10H 20/82; H10H 20/825; H10H 20/831

(57) ABSTRACT

A semiconductor light-emitting device includes a semiconductor light-emitting element, a substrate, and a joining member. The semiconductor light-emitting element includes a semiconductor structure layer, a light shielding layer, and a pair of element electrodes. The semiconductor structure layer includes a semiconductor layer having a light-emitting layer. The light-emitting layer emits a blue light. The light shielding layer is formed to cover a lower surface of the semiconductor structure layer and shields the blue light. The pair of element electrodes are electrically connected to the semiconductor layer via openings formed in the light shielding layer. The substrate has an upper surface with an element mounting region on which the semiconductor light-emitting element is mounted and includes a pair of mounting electrodes. The pair of mounting electrodes each have a mounting portion and expanding portion. The mounting portion is in the element mounting region and opposed to the pair of element electrodes.

### CROSS-REFERENCE TO RELATED APPLICATION

This application is based upon and claims the benefit of priority from Japanese patent application No. 2025-20599, filed on Feb. 12, 2025, the disclosure of which is incorporated herein in its entirety by reference.

### BACKGROUND

### 1. Technical Field

The present invention relates to a semiconductor light-emitting device including a semiconductor light-emitting element.

### 2. Description of the Related Art

A light-emitting device including a light-emitting element that emits a blue light has been disclosed. For example, JP-A-2012-195350 discloses a light-emitting device that includes a substrate and a light-emitting element that is joined onto the substrate using an epoxy resin adhesive or a gold tin (Au—Sn) solder and emits a blue light.

In the light-emitting device disclosed in JP-A-2012-195350, for example, when an epoxy resin adhesive is used as a joining member between the light-emitting element and the substrate, a part of the blue light emitted from the light-emitting element sometimes reaches the adhesive.

While the epoxy resin included in this joining member is low in price compared with, for example, the gold tin solder, it has the property that degradation, such as yellowing or decomposition, easily progresses by a light in a blue wavelength range. Accordingly, for example, when the light-emitting device disclosed in JP-A-2012-195350 is driven for a long period of time, the degradation of the adhesive may progress to possibly weaken the bonding strength between the substrate and the light-emitting element.

The present invention has been made in consideration of the above, and provides a semiconductor light-emitting device that is low in price and allows for suppressing degradation of a joining member that joins a substrate to a light-emitting element.

A semiconductor light-emitting device according to the present invention includes a semiconductor light-emitting element, a substrate, and a joining member. The semiconductor light-emitting element includes a semiconductor structure layer, a light shielding layer, and a pair of element electrodes. The semiconductor structure layer includes a semiconductor layer having a light-emitting layer. The light-emitting layer emits a blue light. The light shielding layer is formed to cover a lower surface of the semiconductor structure layer and shields the blue light. The pair of element electrodes are electrically connected to the semiconductor layer via openings formed in the light shielding layer. The substrate has an upper surface with an element mounting region on which the semiconductor light-emitting element is mounted and includes a pair of mounting electrodes. The pair of mounting electrodes each have a mounting portion and an expanding portion. The mounting portion is disposed in the element mounting region and is opposed to the pair of element electrodes. The expanding portion extends from the mounting portion and extends toward outside of the element mounting region. The joining member includes a metal portion and a resin portion. The metal portion is made of a metal and joins the mounting portion of the pair of mounting electrodes to the pair of element electrodes. The resin portion is made of an epoxy resin and covers a surface of the metal portion and joins the semiconductor light-emitting element to the substrate.

### BRIEF DESCRIPTION OF THE DRAWINGS

FIG. 1 is a perspective view of a light-emitting device according to Embodiment 1;

FIG. 2 is a top view of the light-emitting device according to Embodiment 1;

FIG. 3 is a bottom view of the light-emitting device according to Embodiment 1;

FIG. 4 is a cross-sectional view of the light-emitting device according to Embodiment 1;

FIG. 5 is a top view of a light-emitting element in the light-emitting device according to Embodiment 1;

FIG. 6 is a cross-sectional view of the light-emitting element in the light-emitting device according to Embodiment 1; and

FIG. 7 is a cross-sectional view of a light-emitting device according to a modification of Embodiment 1.

### DETAILED DESCRIPTION

The following describes embodiments of the present invention in detail with reference to the drawings. Note that, in the drawings, the same reference numerals are assigned to identical components, and repeated descriptions thereof are omitted.

### Embodiment 1

### Outline of Light-Emitting Device 100

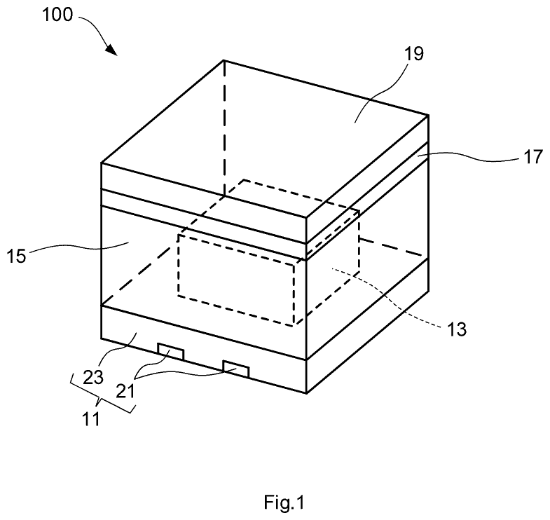

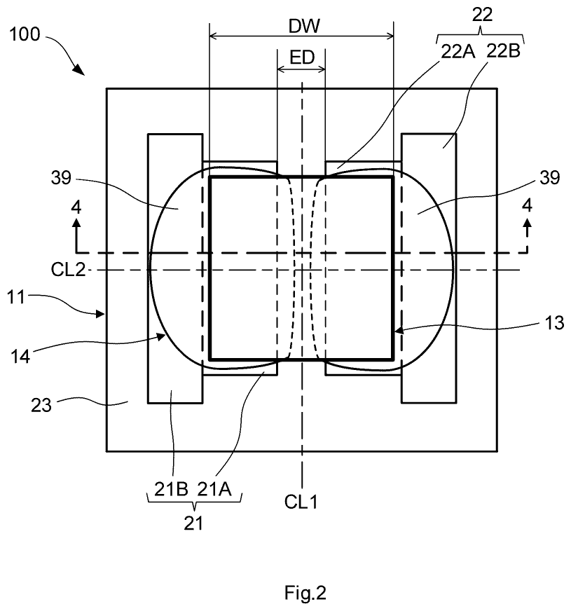

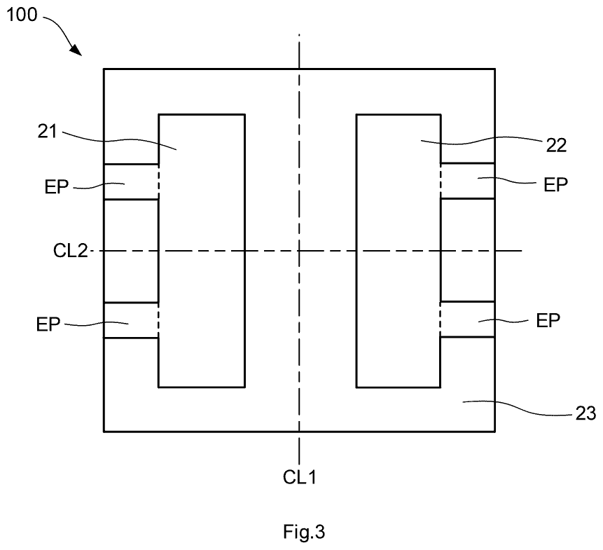

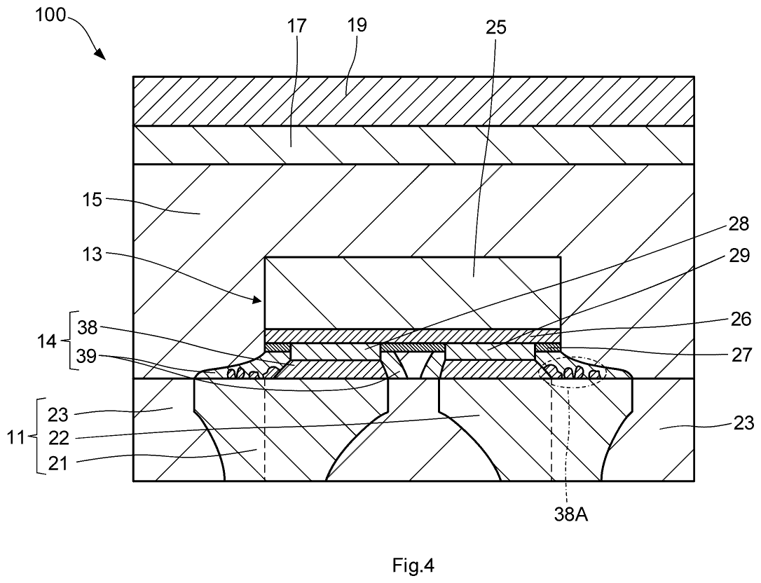

Using FIG. 1 to FIG. 4, a configuration of a light-emitting device 100 according to Embodiment 1 will be described. FIG. 1 is a perspective view of the light-emitting device 100 according to Embodiment 1. FIG. 2 is a top view of the light-emitting device 100 according to Embodiment 1. FIG. 3 is a bottom view of the light-emitting device 100 according to Embodiment 1. FIG. 4 is a cross-sectional view taken along the line 4-4 of the light-emitting device 100 in FIG. 2.

As illustrated in FIG. 1 and FIG. 4, the light-emitting device 100 is configured to include a substrate 11, a light-emitting element 13 disposed on the substrate 11, a joining member 14 that joins the substrate 11 to the light-emitting element 13, a phosphor layer 15 formed to include the light-emitting element 13 on the substrate 11, a sealing layer 17 continuously formed over an upper surface of the phosphor layer 15, and a transmissive-reflective layer 19 continuously formed over an upper surface of the sealing layer 17. Note that the transmissive-reflective layer 19 may be directly formed on the upper surface of the phosphor layer 15 without forming the sealing layer 17.

Note that, in FIG. 2 and FIG. 3, a center line in a width direction (right-left direction in the drawings) of the light-emitting device 100 is indicated by a one-dot chain line as a center line CL1, and a center line in the up-down direction in the drawings of the light-emitting device 100 is indicated by a two-dot chain line as a center line CL2.

In FIG. 2, the phosphor layer 15, the sealing layer 17, and the transmissive-reflective layer 19 are not illustrated in order to avoid complication in illustration. Note that, in FIG. 4, the up-down direction in the drawing is the height direction of the light-emitting device 100.

### Substrate 11

First, the substrate 11 will be described. The substrate 11 is a plate-shaped lead frame substrate having a rectangular top surface shape. The substrate 11 is configured to include a first mounting electrode 21 and a second mounting electrode 22 as electrode bodies, and a resin member 23 made of a resin.

The first mounting electrode 21 and the second mounting electrode 22 are metal bodies disposed to be separated from one another on the same plane. The first mounting electrode 21 and the second mounting electrode 22 each have a narrowing shape that narrows down from an upper surface to a lower surface as illustrated in FIG. 4. In the light-emitting device 100, the resin member 23 is formed around the first mounting electrode 21 and the second mounting electrode 22 and they are integrated, and thus, the substrate 11 is constituted.

The first mounting electrode 21 and the second mounting electrode 22 have a first mounting portion 21A and a second mounting portion 22A, respectively, and the first mounting portion 21A and the second mounting portion 22A have rectangular top surface shapes on the upper surfaces as illustrated in FIG. 2. In the light-emitting device 100 of the embodiment, a long side of the first mounting portion 21A and a long side of the second mounting portion 22A are opposed with the center line CL1 interposed therebetween.

In the light-emitting device 100 of the embodiment, the first mounting portion 21A and the second mounting portion 22A are disposed in an element mounting region when the light-emitting element 13 is mounted on the substrate 11. In other words, the substrate 11 has a pair of mounting portions disposed in the element mounting region.

The first mounting electrode 21 and the second mounting electrode 22 have a first expanding portion 21B and a second expanding portion 22B, respectively, and the first expanding portion 21B and the second expanding portion 22B expand outward from long sides farther from the center line CL1 between the first mounting portion 21A and the second mounting portion 22A on the upper surfaces, and have respective rectangular top surface shapes. In other words, the substrate 11 has a pair of expanding portions expanding to the outside of the element mounting region from the pair of respective mounting portions.

Hereinafter, the first mounting portion 21A and the second mounting portion 22A are also referred to as mounting portions (21A, 22A) when they are not specifically distinguished. Also, the first expanding portion 21B and the second expanding portion 22B are also referred to as expanding portions (21B, 22B) when they are not specifically distinguished.

The first mounting electrode 21 and the second mounting electrode 22 each have two extending portions EP disposed with the center line CL2 interposed therebetween. The extending portions EP extend along the center line CL2 on a lower surface of the substrate 11 and reach outer edges of the substrate 11 as illustrated in FIG. 3.

In the light-emitting device 100 of the embodiment, the first mounting electrode 21 and the second mounting electrode 22 each function as an electrode when the substrate 11 is mounted on a mounting substrate. That is, when the light-emitting device 100 is mounted on the mounting substrate, a current flows from a lower surface to an upper surface of one of the first mounting electrode 21 and the second mounting electrode 22, the current flows into the light-emitting element 13 mounted on the upper surface, and thereafter, the current flows to a lower surface of the other electrode, and thus, the light-emitting element 13 emits a light.

The first mounting electrode 21 and the second mounting electrode 22 each have a base material of copper (Cu), and are constituted of nickel (Ni) and argentum (Ag) stacked in this order on a surface of the base material. Hereinafter, the stacking of the metals on the base material is also referred to as Ni/Ag.

Aluminum (Al), iron-nickel-cobalt alloy (Fe—Ni—Co), or the like may also be used for the base material. Titanium (Ti)/gold (Au), Ni/Au, Ti/Ag, or the like may also be used for the surface of the base material.

The resin member 23 is a resin body with an insulating property continuously covering respective side surfaces of the first mounting electrode 21 and the second mounting electrode 22. That is, in the substrate 11, the upper surfaces and the lower surfaces of the first mounting electrode 21 and the second mounting electrode 22 are exposed from the resin member 23, and the first mounting electrode 21 and the second mounting electrode 22 are insulated from one another due to the presence of the resin member 23 between the first mounting electrode 21 and the second mounting electrode 22.

In the light-emitting device 100 of the embodiment, the resin member 23 is an epoxy resin as a matrix material (medium resin) containing titanium dioxide (TiO₂) particles as light scattering particles. Note that a silicone resin may also be used for the matrix material in addition the epoxy resin.

### Light-Emitting Element 13

Next, the light-emitting element 13 will be described. The light-emitting element 13 is an element having a rectangular top surface shape, and joined to the upper surface of the substrate 11 via the joining member 14. The light-emitting element 13 is a light-emitting diode (LED) having an aluminum gallium nitride (AlGaN)-based semiconductor structure layer. The light-emitting element 13 emits a blue light with, for example, a wavelength of 430 nm to 490 nm.

The light-emitting element 13 is configured to include a supporting substrate 25, a semiconductor structure layer 26 formed of a semiconductor layer disposed on a surface of the supporting substrate 25, a light shielding layer 27 that covers a surface of the semiconductor structure layer 26, a first element electrode 28 and a second element electrode 29 electrically connected to the semiconductor structure layer 26 via openings formed in the light shielding layer 27 as illustrated in FIG. 4.

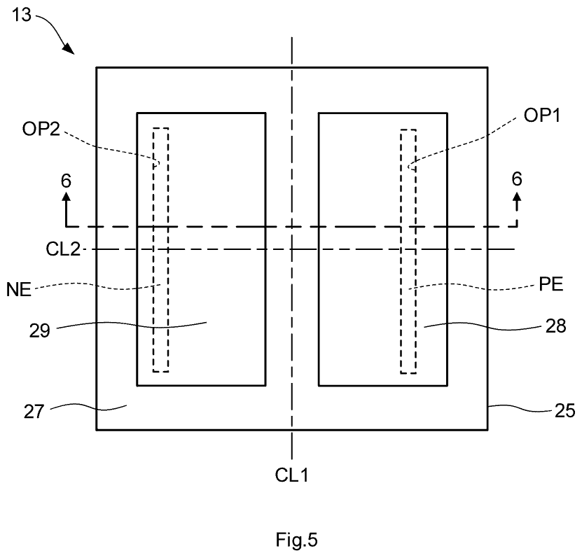

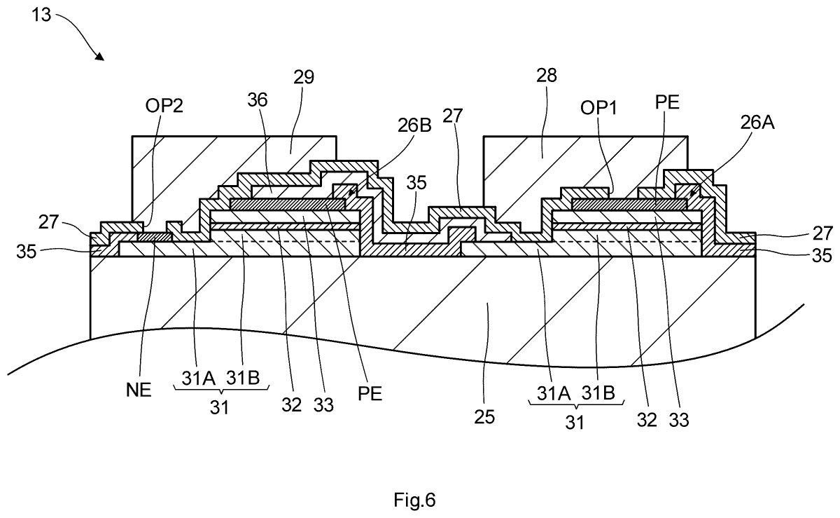

Here, a specific configuration of the light-emitting element 13 will be described using FIG. 5 and FIG. 6. FIG. 5 is a top view of the light-emitting element 13. FIG. 6 is a cross-sectional view of the light-emitting element 13 along the line 6-6 in FIG. 5. In FIG. 5 and FIG. 6, the light-emitting element 13 illustrated in FIG. 1 to FIG. 4 is illustrated in an upside-down orientation. That is, in FIG. 5 and FIG. 6, the lower surface of the light-emitting element 13 illustrated in FIG. 1 to FIG. 4 is described as the upper surface.

The supporting substrate 25 is a flat plate-shaped insulating substrate having a rectangular top surface shape. The supporting substrate 25 is made of a material transmissive to the blue light emitted from the light-emitting layer included in the semiconductor structure layer 26, such as sapphire (Al₂O₃) or gallium nitride (GaN).

The semiconductor structure layer 26 is configured to include a semiconductor stacked body having a plurality of semiconductors stacked on the supporting substrate 25, and electrodes disposed on the semiconductor stacked body. In the light-emitting device 100 of the embodiment, the semiconductor structure layer 26 is constituted of a semiconductor structure layer 26A and a semiconductor structure layer 26B formed to be aligned on the supporting substrate 25.

The semiconductor structure layer 26A and the semiconductor structure layer 26B each have a rectangular top surface shape with a direction along the center line CL1 as a longitudinal direction, and are aligned to be separated from one another along the center line CL2 on the upper surface of the supporting substrate 25. The semiconductor structure layer 26A and the semiconductor structure layer 26B are each constituted of an n-type semiconductor layer 31, a light-emitting layer 32, and a p-type semiconductor layer 33 stacked in this order.

The n-type semiconductor layer 31 is a semiconductor layer in which electrons are charge carriers, and includes a flat plate-shaped lower portion 31A disposed on the upper surface of the supporting substrate 25 and an upper portion 31B projecting from the lower portion 31A. In other words, the n-type semiconductor layer 31 has a mesa-shaped structure (hereinafter also referred to as a mesa structure).

The light-emitting layer 32 is a semiconductor layer that is formed over an upper surface of the upper portion 31B of the n-type semiconductor layer 31 and emits light through recombination of electrons and holes. While the light-emitting element 13 is driven, the light-emitting layer 32 emits a blue light with a peak wavelength of 450 nm.

The p-type semiconductor layer 33 is a semiconductor layer in which holes are charge carriers, and is formed over an upper surface of the light-emitting layer 32. Note that the n-type semiconductor layer 31, the light-emitting layer 32, and the p-type semiconductor layer 33 may appropriately include a semiconductor layer doped with impurities, a semiconductor layer not doped with impurities, a strain relief layer that reduces a strain between layers, a composition gradient layer in which the crystal composition is gradually changed, a quantum well layer having a quantum effect, a barrier layer that suppresses carrier diffusion, or the like corresponding to the purpose.

An n-type electrode NE is an electrode formed on an upper surface of the lower portion 31A of the n-type semiconductor layer 31 in the semiconductor structure layer 26B, and having a rectangular top surface shape with the direction along the center line CL1 as a longitudinal direction. The n-type electrode NE is formed at a position separated from a side surface of the upper portion 31B by a predetermined distance on the upper surface of the lower portion 31A of the n-type semiconductor layer 31.

The n-type electrode NE is formed of Ti/Al/Ti/Au stacked on the upper surface of the lower portion 31A of the n-type semiconductor layer 31 in the semiconductor structure layer 26B. The n-type electrode NE functions as an ohmic electrode that forms a satisfactory ohmic contact with the n-type semiconductor layer 31.

The p-type electrode PE is an electrode formed on an upper surface of the p-type semiconductor layer 33 of each of the semiconductor structure layer 26A and the semiconductor structure layer 26B, and having a rectangular top surface shape with the direction along the center line CL1 as a longitudinal direction. The p-type electrode PE is made of light-transmissive indium tin oxide (ITO). The p-type electrode PE functions as an ohmic electrode that forms a satisfactory ohmic contact with the p-type semiconductor layer 33. The p-type electrode PE may be formed of a metallic material, and for example, is made of Ag.

An insulating layer 35 is a coating layer having an insulating property partially covering the surface of each of the semiconductor structure layer 26A and the semiconductor structure layer 26B on the upper surface of the supporting substrate 25. In the light-emitting device 100 of the embodiment, the insulating layer 35 is made of silicon dioxide (SiO₂).

The insulating layer 35 covers a region along an outer edge of the upper surface of the supporting substrate 25, an end portion of the lower portion 31A of the n-type semiconductor layer 31 in the semiconductor structure layer 26B, and side surfaces of the n-type semiconductor layer 31, the light-emitting layer 32, and the p-type semiconductor layer 33 in the semiconductor structure layer 26A. That is, the insulating layer 35 is formed to surround the semiconductor structure layer 26A and the semiconductor structure layer 26B on the supporting substrate 25.

In addition, while covering the region between the semiconductor structure layer 26A and the semiconductor structure layer 26B on the upper surface of the supporting substrate 25, the insulating layer 35 covers side surfaces of the n-type semiconductor layer 31, the light-emitting layer 32, and the p-type semiconductor layer 33 in the semiconductor structure layer 26B and an end portion of the lower portion 31A of the n-type semiconductor layer 31 in the semiconductor structure layer 26A.

A crossover wiring 36 is a metal wiring that extends from on the lower portion 31A of the n-type semiconductor layer 31 in the semiconductor structure layer 26A onto the insulating layer 35, and reaches the p-type electrode PE of the semiconductor structure layer 26B. The crossover wiring 36 is formed of Ni and Al stacked in this order on the lower portion 31A of the semiconductor structure layer 26A, the insulating layer 35, and the p-type electrode PE of the semiconductor structure layer 26B.

Note that the crossover wiring 36 preferably uses a metal that reflects the light emitted from the light-emitting layer 32 of each of the semiconductor structure layer 26A and the semiconductor structure layer 26B as a material, and, for example, Ag, platinum (Pt), palladium (Pd), rhodium (Rh), or the like may be used instead of Al.

The light shielding layer 27 is a coating layer that has an insulating property that continuously covers the surfaces of the semiconductor structure layer 26A and the semiconductor structure layer 26B. The light shielding layer 27 is a dielectric multilayer film in which a plurality of dielectric films are stacked so as to obtain a layer thickness that reflects the blue light emitted from the light-emitting layer 32.

The light shielding layer 27 is provided with an opening OP1 having a rectangular top surface shape that partially exposes the p-type electrode PE of the semiconductor structure layer 26A as illustrated in FIG. 5 and FIG. 6. The light shielding layer 27 is provided with an opening OP2 having a rectangular top surface shape that partially exposes the n-type electrode NE of the semiconductor structure layer 26B.

In the light-emitting device 100 of the embodiment, the light shielding layer 27 is formed of 48 layers (24 sets) of SiO₂ and Al₂O₃ alternately stacked. Note that, for the constituent material of the light shielding layer 27, TiO₂, niobium oxide (NbO), magnesium oxide (MgO), tantalum oxide (Ta₂O₅), hafnium oxide (HfO), or the like may be used.

In the light-emitting device 100 of the embodiment, the crossover wiring 36 covered with the light shielding layer 27 connects the n-type semiconductor layer 31 in the semiconductor structure layer 26A to the p-type electrode PE in the semiconductor structure layer 26B, and thus, electrically connects the semiconductor structure layer 26A to the semiconductor structure layer 26B in series. That is, in the light-emitting element 13, the p-type electrode PE in the semiconductor structure layer 26A is an electrode at one end of the series connection, and the n-type electrode NE in the semiconductor structure layer 26B is an electrode at the other end of the series connection.

The first element electrode 28 is an electrode pad that has a rectangular top surface shape with the direction along the center line CL1 as a longitudinal direction, and is formed to cover the p-type electrode PE while being in contact with the p-type electrode PE exposed from the opening OP1 on the semiconductor structure layer 26A. The first element electrode 28 is electrically connected to the semiconductor structure layer 26A via the p-type electrode PE that is exposed from the opening OP1.

Similarly, the second element electrode 29 is an electrode pad that has a rectangular top surface shape with the direction along the center line CL1 as a longitudinal direction, and is formed to cover the n-type electrode NE while being in contact with the n-type electrode NE exposed from the opening OP2 on the semiconductor structure layer 26B. The second element electrode 29 is electrically connected to the semiconductor structure layer 26B via the n-type electrode NE that is exposed from the opening OP2. Hereinafter, the first element electrode 28 and the second element electrode 29 are also referred to as element electrodes (28, 29) when they are not specifically distinguished.

The first element electrode 28 and the second element electrode 29 are formed to be separated from one another across the center line CL1 in top view as illustrated in FIG. 5. In the light-emitting device 100 of the embodiment, the element electrodes (28, 29) are formed of Ni, Al, Ti, and Au stacked in this order.

The first element electrode 28 functions as an anode electrode that receives supply of an electric power from outside and applies a voltage on the p-type semiconductor layer 33 via the p-type electrode PE. The second element electrode 29 functions as a cathode electrode that receives supply of an electric power from outside and applies a voltage on the n-type semiconductor layer 31 via the n-type electrode NE.

As described above, in the light-emitting device 100 of the embodiment, the first element electrode 28 as the anode electrode is connected via the p-type electrode PE that forms the one end of the series connection and is exposed from the opening OP1, and the second element electrode 29 as the cathode electrode is connected via the n-type electrode NE that forms the other end of the series connection and is exposed from the opening OP2.

Accordingly, in the light-emitting device 100 of the embodiment, application of a voltage to each of the semiconductor structure layer 26A and the semiconductor structure layer 26B connected in series via the first element electrode 28 and the second element electrode 29 causes a current to flow to the respective light-emitting layers 32 of the semiconductor structure layer 26A and the semiconductor structure layer 26B, and a blue light is emitted.

In the light-emitting device 100 of the embodiment, the light shielding layer 27 made of a dielectric multilayer film is formed on the light-emitting element 13, and thus, the blue light emitted from the light-emitting element 13 is reflected by the light shielding layer 27. The blue light after being reflected is emitted to sides of the light-emitting element 13 or transmits through the supporting substrate 25 and is emitted downward in FIG. 6.

Refer to FIG. 1 to FIG. 4 again. The first element electrode 28 and the second element electrode 29 of the light-emitting element 13 are joined to the first mounting electrode 21 and the second mounting electrode 22, respectively, of the substrate 11 via the joining member 14. That is, in the light-emitting device 100 of the embodiment, the light-emitting element 13 is flip-chip mounted on the substrate 11.

Note that, in the light-emitting device 100 of the embodiment, a distance ED (see FIG. 2) between the first mounting portion 21A and the second mounting portion 22A is one-fifth or more and one-third or less of a width DW in the direction along the center line CL2 of the light-emitting element 13. This allows for avoiding a short circuit between the mounting portions (21A, 22A) while ensuring a heat-dissipation performance of the heat generated while the light-emitting element 13 is driven.

### Joining Member 14

The joining member 14 is a joining member including a metal portion 38 made of a metal, and a resin portion 39 made of a resin. The joining member 14 used for the light-emitting device 100 of the embodiment is, what is called an epoxy solder, which is a hardened solder paste containing a resin component made of an epoxy resin and a solder component made of solder metal microparticles.

The metal portions 38 joins the first element electrode 28 and the second element electrode 29 of the light-emitting element 13 to the first mounting portion 21A and the second mounting portion 22A of the substrate 11, respectively. The metal portion 38 is the aggregated and hardened solder component in the solder paste as the joining member 14 before hardening used when the light-emitting element 13 is joined to the substrate 11, and is made of tin-silver-copper (Sn—Ag—Cu) in the light-emitting device 100.

The resin portion 39 covers a surface of the metal portion 38 and joins the light-emitting element 13 to the substrate 11. Specifically, the resin portion 39 joins surfaces of the light shielding layer 27 of the light-emitting element 13, the respective side surfaces of the first element electrode 28 and the second element electrode 29, and parts of the first mounting electrode 21, the second mounting electrode 22, and the resin member 23 of the substrate 11.

The resin portion 39 is the hardened epoxy resin component in the solder paste as the joining member 14 before hardening used when the light-emitting element 13 is joined to the substrate 11. In the joining member 14, the resin portion 39 enhances the joining strength between the substrate 11 and the light-emitting element 13 after joining the light-emitting element 13 to the substrate 11.

The resin portion 39 covers the surface of the metal portion 38 and extends to the outside of the element mounting region of the light-emitting element 13 to reach the expanding portions (21B, 22B) on the substrate 11. In other words, the resin portion 39 extends across the respective mounting portions (21A, 22A) and expanding portions (21B, 22B) of the first mounting electrode 21 and the second mounting electrode 22.

On the expanding portions (21B, 22B), solder scattered portions 38A in which the solder component in the solder paste failed to aggregate as the metal portion 38 is scattered are formed in the joint portions between the mounting portions (21A, 22A) of the substrate 11 and the element electrodes (28, 29) of the light-emitting element 13. That is, the solder scattered portions 38A are made of a material identical to that of the metal portion 38. The resin portion 39 includes the solder scattered portions 38A and extends onto the expanding portions (21B, 22B) in the joining member 14.

### Phosphor Layer 15

Next, the phosphor layer 15 will be described. The phosphor layer 15 has a rectangular top surface shape and is disposed to encompass the light-emitting element 13 on the substrate 11. The phosphor layer 15 includes a phosphor that emits a fluorescence by being excited by a blue light as an excitation light emitted from the light-emitting element 13.

The phosphor layer 15 is a light-transmissive medium resin caused to contain a first phosphor that emits a red fluorescence having a peak wavelength of approximately 630 nm by receiving a blue light emitted from the light-emitting element 13 and a second phosphor that emits a green fluorescence having a peak wavelength of approximately 540 nm by receiving the blue light (both of them are not illustrated)

In the light-emitting device 100 of the embodiment, the medium resin is made of a phenyl-based silicone resin having a siloxane bonding (Si—O—Si) as main chain and a methyl group (—CH₃) and a phenyl group (—C₆H₅) bonded to the silicon (Si) in the siloxane bonding as a side chain.

In the light-emitting device 100 of the embodiment, the first phosphor is a KSF (K₂SiF₆:Mn⁴⁺) phosphor in which manganese (Mn) is added as an activator agent to potassium fluorosilicate (K₂SiF₆) as a mother crystal. The second phosphor is a β-sialon (β-SiAlON:Eu²⁺) phosphor in which europium (Eu) is added as an activator agent.

In the light-emitting device 100 of the embodiment, the first phosphor and the second phosphor each have a particle diameter of 10 μm to 35 μm, and respective additive amounts of the first phosphor and the second phosphor to the respective medium resins are approximately 35 wt %. Weight compounding ratios of the first phosphor and the second phosphor to the medium resin is 70:30.

When the blue light emitted from the light-emitting element 13 enters the phosphor layer 15, a part thereof directly transmits through the medium resin in the phosphor layer 15, and a part excites the first phosphor and the second phosphor, and thus the fluorescence is emitted from the excited phosphors.

Accordingly, the excitation light that has passed through the medium resin without contributing to the fluorescence generation and the fluorescence emitted from the first phosphor and the second phosphor are emitted from an upper surface of the phosphor layer 15. This emits a white light in which the blue light, the red fluorescence, and the green fluorescence are mixed from the upper surface of the phosphor layer 15.

### Sealing Layer 17

Next, the sealing layer 17 will be described. The sealing layer 17 is a light-transmissive layer continuously formed over the upper surface of the phosphor layer 15. The sealing layer 17 is made of a silicone resin that, for example, transmits a white light (in detail, a white band light). The sealing layer 17 functions as a light guiding layer that guides the white light emitted from the phosphor layer 15.

### Transmissive-Reflective Layer 19

Next, the transmissive-reflective layer 19 will be described. The transmissive-reflective layer 19 is a layer that is continuously formed over an upper surface of the sealing layer 17, and reflects a part of the white light guided by the sealing layer 17 to be emitted therethrough and transmits a part thereof.

In the light-emitting device 100 of the embodiment, the transmissive-reflective layer 19 is constituted of a silicone resin including TiO₂ particles having an adjusted concentration such that the transmittance and the reflectance with respect to the white light have predetermined values. Note that a dielectric multilayer film whose layer thickness is adjusted such that the transmittance and the reflectance with respect to the white light have predetermined values may be used for the transmissive-reflective layer 19.

The light emitted from the light-emitting device 100 has what is called a batwing light distribution, which is a light distribution with which the light intensity immediately above the light-emitting device 100 is reduced, and the light intensity on the sides is enhanced. That is, the light emitted from the light-emitting device 100 has a light distribution (half-value angle 140° to 180°) with an angle wider than that of a Lambertian light distribution Lambertian distribution (half-value angle 120°) that has the light intensity becoming lower from the immediately above the light-emitting device 100 toward the sides.

The light-emitting device 100 having such a batwing light distribution may be used in an environment where a light with a highly uniform luminance distribution over a wide range, such as a light source of an auxiliary light for a vehicle, a light source of a direct backlight for an LCD-TV, or the like is required.

### Suppression of Degradation of Resin Portion 39 in Joining Member 14

Here, using FIG. 4, a description will be given of suppression of degradation of the resin portion 39 in the joining member 14 while the light-emitting element 13 of the embodiment is driven.

In the light-emitting device 100 of the embodiment, the solder paste including the resin component made of the epoxy resin and the solder component made of Sn—Ag—Cu as the joining member 14 before hardening is applied on the mounting portions (21A, 22A) of the substrate 11, and the light-emitting element 13 is mounted thereon, and thereafter, a reflow process is performed to achieve hardening, thereby joining the substrate 11 to the light-emitting element 13.

In this reflow process, the solder component in the solder paste is aggregated and hardened after being melted on the mounting electrodes (21A, 21B), and thus, becomes the metal portion 38 that joins the mounting electrodes (21A, 21B) of the substrate 11 to the element electrodes (28, 29) of the light-emitting element 13.

In this reflow process, the resin component in the solder paste takes an aspect of covering the aggregated solder component in association with the aggregation of the solder component, and thus, becomes the resin portion 39 covering the surface of the metal portion 38 after hardening. At this time, the resin portion 39, while covering the solder component, wets and spreads also the outside of the mounting electrodes (21A, 21B) of the substrate 11.

In the light-emitting device 100 of the embodiment, the first mounting electrode 21 and the second mounting electrode 22 have the respective expanding portions (21B, 22B) extending from the mounting portions (21A, 21B) as described above. This causes the resin portion 39 before hardening to continue to spread over the expanding portions (21B, 22B) when the resin portion 39 before hardening spreads toward the outside of the mounting portions (21A, 21B) from the mounting portions (21A, 21B).

Accordingly, when the resin portion 39 before hardening hardens, the resin portion 39 is in contact with only the surface of the light shielding layer 27 of the light-emitting element 13 and the respective side surfaces of the first element electrode 28 and the second element electrode 29, and joins them to the substrate 11. That is, the light-emitting element 13 is joined to the substrate 11 only on the lower surface of the light-emitting element 13 via the joining member 14 made of the metal portion 38 and the resin portion 39.

For example, when the first mounting electrode 21 and the second mounting electrode 22 do not have respective expanding portions (21B, 22B), the resin portion 39 before hardening possibly climbs up to the side surfaces of the light-emitting element 13 through the lower surface of the light-emitting element 13 when the resin portion 39 before hardening spreads to the outside of the mounting electrodes (21A, 21B) of the substrate 11. That is, there is a risk that, after the hardening of the resin portion 39, the resin portion 39 could end up being formed so as to cover the side surfaces of the light-emitting element 13.

The epoxy resin that constitutes the resin portion 39 is degraded, for example, discolored or decomposed, by receiving a light in a blue wavelength range for a long period of time. Accordingly, for example, if the resin portion 39 were formed on side surfaces of the supporting substrate 25, the resin portion 39 is directly irradiated with the blue light emitted from the light-emitting element 13, which could easily degrade the resin portion 39.

If such an event occurs, the resin portion 39 physically blocking the blue light emitted from the light-emitting element 13 possibly causes decreased optical output, and the degradation of the resin portion 39 possibly leads peeling or the like.

The light-emitting device 100 of the embodiment allows for preventing the resin portion 39 from being directly irradiated with the blue light emitted from the light-emitting element 13 since the substrate 11 is adhered only on the lower surface of the light-emitting element 13 as described above. That is, degradation of the resin portion 39 caused by the blue light can be suppressed.

In the light-emitting device 100 of the embodiment, the light shielding layer 27 made of the dielectric multilayer film is formed to cover the semiconductor structure layer 26A and the semiconductor structure layer 26B as described above. This causes the blue light emitted from the respective light-emitting layers 32 of the semiconductor structure layer 26A and the semiconductor structure layer 26B to be reflected by the light shielding layer 27 before reaching the joining member 14.

Accordingly, the light-emitting device 100 of the embodiment includes the expanding portions (21B, 22B) and the light shielding layer 27 described above, which causes the blue light emitted from the light-emitting element 13 to be less likely to reach the resin portion 39 constituting the joining member 14.

Accordingly, the light-emitting device 100 of the embodiment allows for preventing the resin portion 39 from being degraded by inhibiting the resin portion 39 from being irradiated with the blue light. That is, the joining between the light-emitting element 13 and the substrate 11 can be properly maintained.

The epoxy solder used in the joining member 14 in the light-emitting device 100 of the embodiment is low-price compared with an Au—Sn solder or the like generally used for joining the light-emitting element 13 that emits the blue light to the substrate. Accordingly, the light-emitting device 100 of the embodiment allows for providing a semiconductor light-emitting device that is low in price and allows for suppressing degradation of the joining member joining the substrate to the light-emitting element.

In the light-emitting device 100 of the embodiment, the resin portion 39 includes the solder scattered portions 38A on the expanding portions (21B, 22B) as described above. The intensity of the blue light that enters the resin portion 39 on the expanding portions (21B, 22B) is weak in the light-emitting device 100, and also even if the blue light enters, a part thereof is absorbed by the metal of the solder scattered portion 38A. For example, a part of the light scattered by the phosphor included in the phosphor layer 15 of the blue light emitted from the light-emitting element 13 enters the resin portion 39 on the expanding portions (21B, 22B) and is absorbed by the solder scattered portions 38A.

Accordingly, with the light-emitting device 100 of the embodiment, even if the blue light emitted from the light-emitting element 13 reaches the resin portion 39 spread on the expanding portions (21B, 22B), a part is absorbed by the solder scattered portions 38A, and therefore, the degradation of the epoxy resin constituting the resin portion 39 can be suppressed.

When the light-emitting device 100 of the embodiment is joined to a circuit board by solder reflow or the like, the metal portion 38 of the joining member 14 may be melted again depending on the heating temperature during reflowing. The light-emitting device 100 of the embodiment, however, can prevent, for example, an energization failure or the like from occurring in the light-emitting element 13 since the resin portion 39 maintains the joining between the light-emitting element 13 and the substrate 11.

While in the light-emitting device 100 of the embodiment, the light-emitting element 13 is flip-chip mounted on the substrate 11, the method of mounting the light-emitting element 13 is not limited to this. For example, the light-emitting element 13 may have a lower surface electrode and an upper surface electrode to which a bonding wire is connected, and the lower surface electrode may be joined to the substrate 11 via the joining member 14.

While in the light-emitting device 100 of the embodiment, the light-emitting element 13 is formed of two semiconductor structure layers, the configuration is not limited to this, and three or more semiconductor structure layers may be formed on the supporting substrate 25 and connected in series.

### Modification 1

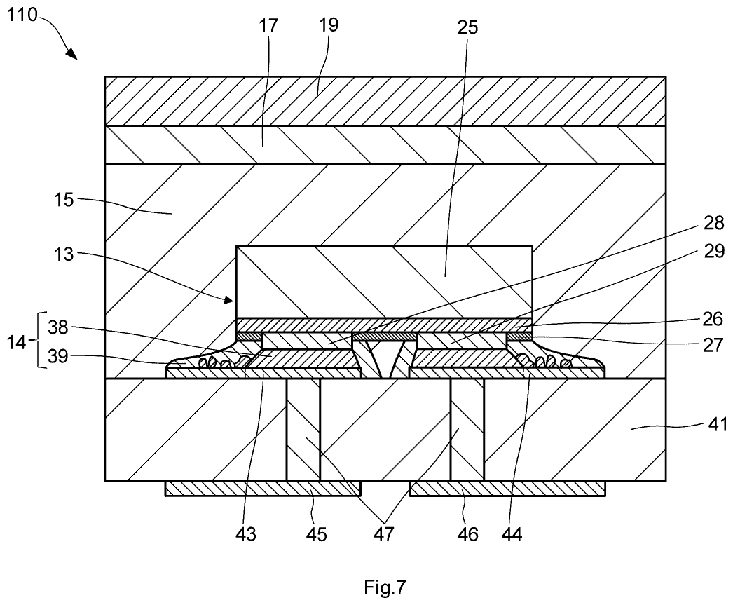

Next, using FIG. 7, a modification according to Embodiment 1 will be described. FIG. 7 is a cross-sectional view of a light-emitting device 110 of Modification 1. The light-emitting device 110 is different from the light-emitting device 100 in Embodiment 1 in a configuration of a substrate on which the light-emitting element 13 is mounted, and other configurations are similar to those in Embodiment 1.

In the light-emitting device 110 of the modification, a substrate 41 is a flat plate-shaped glass epoxy substrate (FR-4) having a rectangular top surface shape and an insulation property. A ceramic substrate formed of alumina (Al₂O₃) or aluminum nitride (AlN) may be used for the substrate 41.

In the light-emitting device 110 of the modification, the substrate 41 has an upper surface on which an anode pad 43 and a cathode pad 44 are formed. The substrate 41 has a lower surface on which an anode electrode 45 and a cathode electrode 46 are formed.

The anode pad 43 and the cathode pad 44 are a pair of element mounted pads formed to be separated from one another with the center line CL1 interposed therebetween on the upper surface of the substrate 41 similarly to Embodiment 1. The anode pad 43 and the cathode pad 44 each have a mounting portion and an expanded portion described above similarly to Embodiment 1.

The anode electrode 45 and the cathode electrode 46 are a pair of electrodes formed to be separated from one another with the center line CL1 interposed therebetween on the lower surface of the substrate 41. In the light-emitting device 110, the anode pad 43 and the anode electrode 45 are electrically connected via a conductive via 47 made of a Cu material. Similarly, the cathode pad 44 and the cathode electrode 46 are electrically connected via the conductive via 47.

Each of the anode pad 43, the cathode pad 44, the anode electrode 45, and the cathode electrode 46 described above is a Cu material, and has a surface on which Ni plating and Au plating are provided in this order. Ag plating may be used instead of the Au plating for the plating process.

The light-emitting device 110 of the modification includes the expanding portions (21B, 22B) and the light shielding layer 27 described above as well, which causes the blue light emitted from the light-emitting element 13 to be less likely to reach the resin portion 39 constituting the joining member 14.

Accordingly, the light-emitting device 110 of the modification allows for preventing the resin portion 39 from being degraded by inhibiting the resin portion 39 from being irradiated with the blue light. That is, the joining between the light-emitting element 13 and the substrate 11 can be properly maintained.

It is understood that the foregoing description and accompanying drawings set forth the preferred embodiments of the present invention at the present time. Various modifications, additions and alternative designs will, of course, become apparent to those skilled in the art in light of the foregoing teachings without departing from the spirit and scope of the disclosed invention. Thus, it should be appreciated that the present invention is not limited to the disclosed Examples but may be practiced within the full scope of the appended claims. The present application is based upon and claims the benefit of priority from the prior Japanese Patent Application No. 2025-020599 filed on Feb. 12, 2025, the entire contents of which are incorporated herein by reference.

### DESCRIPTION OF REFERENCE SIGNS

11, 41 Substrate
13 Light-emitting element
14 Joining member
15 Phosphor layer
17 Sealing layer
19 Transmissive-reflective layer
21 First mounting electrode
22 Second mounting electrode
23 Resin member
25 Supporting substrate
26 Semiconductor structure layer
27 Light shielding layer
28 First element electrode
29 Second element electrode
31 n-type semiconductor layer
32 Light-emitting layer
33 p-type semiconductor layer
35 Insulating layer
36 Crossover wiring
38 Metal portion
39 Resin portion
43 Anode pad
44 Cathode pad
45 Anode electrode
46 Cathode electrode
47 Conductive via

What is claimed is:

1. A semiconductor light-emitting device comprising:
a semiconductor light-emitting element that includes a semiconductor structure layer, a light shielding layer, and a pair of element electrodes, the semiconductor structure layer including a semiconductor layer having a light-emitting layer, the light-emitting layer emitting a blue light, the light shielding layer being formed to cover a lower surface of the semiconductor structure layer and shielding the blue light, the pair of element electrodes being electrically connected to the semiconductor layer via openings formed in the light shielding layer;
a substrate that has an upper surface with an element mounting region on which the semiconductor light-emitting element is mounted and includes a pair of mounting electrodes, the pair of mounting electrodes each having a mounting portion and an expanding portion, the mounting portions being disposed in the element mounting region and being opposed to the pair of element electrodes, the expanding portions extending from the mounting portions and extending toward outside of the element mounting region; and
a joining member that includes a metal portion and a resin portion, the metal portion being made of a metal and joining the mounting portion of the pair of mounting electrodes to the pair of element electrodes, the resin portion being made of an epoxy resin and covering a surface of the metal portion and joining the semiconductor light-emitting element to the substrate.

2. The semiconductor light-emitting device according to claim 1, wherein
the resin portion extends to a surface of the expanding portion.

3. The semiconductor light-emitting device according to claim 2, wherein
metal material constituting the metal portion is scattered on each of the expanding portions, and the resin portion includes the scattered metal material.

4. The semiconductor light-emitting device according to claim 1, wherein
the light shielding layer is a dielectric multilayer film.

5. The semiconductor light-emitting device according to claim 1, wherein
the metal portion is made of Sn—Ag—Cu.

6. The semiconductor light-emitting device according to claim 1, wherein
the substrate is a lead frame including a first electrode body and a second electrode body disposed to be separated from one another and a resin member that continuously covers respective side surfaces of the first electrode body and the second electrode body.

7. The semiconductor light-emitting device according to claim 1, wherein
the substrate includes a base material, the pair of mounting electrodes formed on the upper surface of the substrate, and a pair of lower surface electrodes formed on a lower surface of the substrate, and
each of the mounting portions of the pair of mounting electrodes and each of the pair of lower surface electrodes are connected via a conductive via that passes through the base material.

8. The semiconductor light-emitting device according to claim 1, further comprising
a phosphor layer including a phosphor that is formed on the upper surface of the substrate to cover the semiconductor light-emitting element and is excited by the blue light to emit a fluorescence.

9. The semiconductor light-emitting device according to claim 8, further comprising:
a light-transmissive sealing layer that covers an upper surface of the phosphor layer; and
a transmissive-reflective layer that is formed over an upper surface of the sealing layer, reflects a part of each of the blue light and the fluorescence, and transmits a part of each of the blue light and the fluorescence.

10. The semiconductor light-emitting device according to claim 9, wherein
the transmissive-reflective layer is made of a light-transmissive silicone resin including TiO₂ particles.

11. The semiconductor light-emitting device according to claim 1, wherein
the semiconductor light-emitting element includes a flat plate-shaped supporting substrate and is configured such that a plurality of the semiconductor structure layers formed on the supporting substrate are connected to one another in series.
